(19) United States
(12) Patent Application Publication
(10) Pub. No.: US 2005/0200003 A1
(43) Pub. Date: Sep. 15, 2005

(54) Multi-chip package

(76) Inventors: Ki-myung Yoon, Cheonan-si (KR); Heung-kyu Kwon, Suwon-si (KR); Hee-seok Lee, Suwon-si (KR)

Correspondence Address: HARNESS, DICKEY & PIERCE, P.L.C., P.O. BOX 8910, RESTON, VA, 20195, US

(21) Appl. No.: 11/033,993

(22) Filed: Jan. 13, 2005

(30) Foreign Application Priority Data
Jan. 13, 2004 (KR) 10-2004-0002373

(51) Int. Cl. H01L 21/44; H01L 23/34; H05K 5/00; H05K 5/04; H05K 5/06

(52) U.S. Cl. 257/723; 361/730

(57) ABSTRACT

A multi-chip package may be provided which may include a substrate, on which multiple substrate bonding pads may be formed and under which multiple terminals may be formed, first and second semiconductor chips, which may be deposited on the substrate, and a spacer, which may be formed between the first and second semiconductor chips to have at least power and ground pads. The spacer may be used as passive element, and the first and second semiconductor chips and the power and ground pads of the spacer may be electrically connected. The pads of the semiconductor chip which may be deposited on the spacer may also be electrically connected to substrate bonding pads via the pads which may be formed on the spacer.

### CROSS-REFERENCE TO RELATED APPLICATIONS

This application claims priority of Korean Patent Application No. 10-2004-0002373 filed on Jan. 13, 2004 in the Korean Intellectual Property Office, the disclosure of which is incorporated herein by reference in its entirety.

1. Field of the Invention

The present invention relates to a multi-chip package, more particularly, to a multi-chip package in which multiple chips may be vertically stacked with spacers interposed between each of the chips and the spacers may serve as passive elements.

2. Description of the Related Art

In the portable electronic equipment market, an important challenge may be packing many elements into such equipment as possible.

Several ways may be used to attain thinner, smaller and/or lighter elements, a system-on-a-chip (SOC) technique in which multiple individual elements may be integrated into a single chip, and a system-in-package (SIP) technique in which multiple individual elements may be integrated into a single package.

The SIP technique may be similar to the conventional multi-chip module (MCM) approach, in which multiple silicon chips may be horizontally or vertically mounted in a single package. According to the multi-chip module approach, multiple chips may be mounted in a horizontal direction. According to the SIP technique, chips may be mounted in a vertical direction.

Passive elements, which may be resistors, capacitors and/or inductors, may be arranged and/or mounted on a system board with considering the characteristics of multiple stacked chips and/or power input noise reduction.

The inductance of a capacitor may be determined depending on the proximity of the capacitor to other elements integrated in each chip. Placing the capacitor closer to other elements integrated in each chip may reduce inductance. In the SIP technique, in which multiple chips may be stacked vertically, a spacer, which may provide a space for wire bonding, may be provided between upper and lower chips.

Providing capacitors and spacers in such ways may limit the size reduction of the multi-chip package.

### SUMMARY OF THE INVENTION

The present invention may provide a multi-chip package which may have improved electrical characteristics, and/or may allow a reduction in package size while maintaining wire bonding stability.

In exemplary embodiments of the present invention, there may be provided a multi-chip package, which may comprise a substrate. Multiple substrate bonding pads, which may include at least power and ground pads, may be formed on the substrate and multiple terminals may be formed under the substrate. A first semiconductor chip, may be formed on the substrate and may have multiple pads which may include at least power and ground pads. A spacer, which may be formed on the first semiconductor chip and may have at least one passive element with at least power and ground pads formed thereon. A second semiconductor chip which may be formed on the spacer and may have multiple pads, which may include at least power and ground pads. The multiple pads may electrically connect the first and second semiconductor chips and the power and ground pads of the spacer to the power and ground pads of the substrate bonding pads.

In another exemplary embodiment of the present invention, there may be provided a multi-chip package, which may comprise a substrate. Multiple substrate bonding pads, which may include at least power and ground pads, may be formed on the substrate and multiple terminals may be formed under the substrate. A first semiconductor chip may be formed on the substrate and may have multiple pads, which may include at least power and ground pads. A spacer, may be formed on the first semiconductor chip, and may have at least one passive element with at least power and ground pads which may be formed thereon. The at least one passive element may be longer than the first semiconductor chip in at least one of first and second directions, which may be orthogonal to each other, with respect to the first semiconductor chip. A second semiconductor chip may be formed on the spacer and may have multiple pads including at least power and ground pads which may be electrically connected to the first and second semiconductor chips and the power and ground pads of the spacer to the power and ground pads of the substrate bonding pads.

The second semiconductor chip may have a length in a first direction and another length in a second direction which may be orthogonal to the first direction. The second semiconductor chip may be shorter than the spacer in at least one of the first and second directions of the spacer.

The spacer may be formed of silicon and may have a thickness of 80-120 μm. The at least one passive element, which may be included in the spacer may be a capacitor, and the power and ground pads of the spacer may serve as electrodes of the capacitor.

In another exemplary embodiment of the present invention, there may be provided a multi-chip package, which may comprise a substrate. Multiple substrate bonding pads, which may include at least power and ground pads, may be formed on the substrate and multiple terminals may be formed under the substrate. A first semiconductor chip may be formed on the substrate and may have multiple pads, including at least power and ground pads. A spacer, may be formed on the first semiconductor chip, and may have at least one passive element with at least power and ground pads which may be formed thereon. At least two of the first semiconductor chip, the second semiconductor chip, and the spacer, may be selected such that each of the first semiconductor chip, second semiconductor chip, and spacer which may be selected, may be greater than, less than, or equal in length in at least one of a first and a second direction with respect to the at least one which may not be selected from the group.

A second semiconductor chip may be formed on the spacer and may have multiple pads, including at least power and ground pads, which may electrically connect the first and second semiconductor chips and the power and ground pads of the spacer to the power and ground pads of the substrate bonding pads.

The spacer may be formed of silicon and may have a thickness of 80-120 μm. The at least one passive element which may be included in the spacer may be a capacitor, and the power and ground pads of the spacer may serve as electrodes of the capacitor.

In another exemplary embodiment of the present invention, there may be provided a method of manufacturing a multi-chip package, which may comprise forming multiple substrate bonding pads, including at least power and ground pads, on and multiple terminals under a substrate. Multiple pads, including at least power and ground pads may be formed on a first semiconductor chip, at least one passive element, with at least power and ground pads may be formed on a spacer, and multiple pads including at least power and ground pads formed thereon, may be formed on a second semiconductor chip. The first semiconductor chip, the second semiconductor chip, and the spacer, may be deposited on and/or electrically connected to the substrate, and at least two of the first semiconductor chip, the second semiconductor chip, and the spacer, may each be greater than, less than, or equal in length in at least one of a first and a second direction with respect to the at least one not selected from the group. The first and second directions may be orthogonal to each other.

### BRIEF DESCRIPTION OF THE DRAWINGS

The present invention may become more apparent by describing in detail exemplary embodiments thereof with reference to the attached drawings in which:

FIG. 1 is a plan view of a multi-chip package according to an exemplary embodiment of the present invention;

FIG. 2 is a horizontal cross-sectional view of FIG. 1;

FIG. 3 is a vertical cross-sectional view of FIG. 1;

FIG. 4 is a plan view of a multi-chip package according to another exemplary embodiment of the present invention;

FIG. 5 is a cross-sectional view of FIG. 4;

FIG. 6 is a plan view of a multi-chip package according to another exemplary embodiment of the present invention;

FIG. 7 is a horizontal cross-sectional view of FIG. 6;

FIG. 8 is a vertical cross-sectional view of FIG. 7;

FIGS. 9A, 9B, and 9C are a plan view, a horizontal cross-sectional view, and a vertical cross-sectional view, respectively, illustrating a portion of a method of manufacturing the multi-chip package according to another exemplary embodiment of the present invention;

FIGS. 10A, 10B, and 10C are a plan view, a horizontal cross-sectional view, and a vertical cross-sectional view, respectively, illustrating another portion of the method of manufacturing the multi-chip package according to another exemplary embodiment of the present invention;

FIGS. 11A and 11B are a plan view and a horizontal cross-sectional view, respectively, illustrating another portion of the method of manufacturing the multi-chip package according to another exemplary embodiment of the present invention;

FIG. 12 is a plan view of a variation of the multi-chip package according to another exemplary embodiment of the present invention;

FIG. 13 is a horizontal cross-sectional view of the multi-chip package of FIG. 12; and

FIG. 14 is a vertical cross-sectional view of the multi-chip package of FIG. 12.

### DETAILED DESCRIPTION OF EXEMPLARY EMBODIMENTS OF THE PRESENT INVENTION

Advantages and features of the present invention and methods of accomplishing the same may be understood more readily by reference to the following detailed description of exemplary embodiments and the accompanying drawings. The present invention may be embodied in different forms and should not be construed as being limited to the embodiments set forth herein. These exemplary embodiments are provided such that this disclosure will be thorough and complete and will fully convey the concept of the invention to those skilled in the art, and the present invention will only be defined by the appended claims. Like reference numerals refer to like elements throughout the specification.

In particular, the relative thicknesses and positioning of layers or regions may be reduced or exaggerated for clarity. Further, a layer is considered as being formed “on” another layer or a substrate when formed either directly on the referenced layer or the substrate or formed on other layers or patterns overlaying the referenced layer.

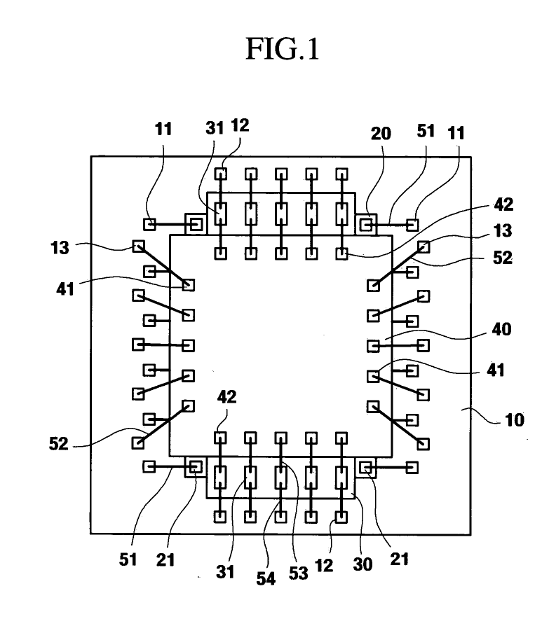

A multi-chip package according to an exemplary embodiment of the present invention will be described more fully with reference to FIGS. 1 through 3.

Referring to FIGS. 1 through 3, in an exemplary embodiment of the present invention, a first chip 20 may be mounted on a substrate 10, on which multiple substrate bonding pads 11, 12, and 13 may be formed, and under which multiple terminals 15 may be formed.

The substrate bonding pad 11 may be connected to the first chip 20, the substrate bonding pad 12 may be connected to a spacer 30, and the substrate bonding pad 13 may be connected to a second chip 40.

The spacer 30, which may be attached to the first chip 20, may be longer than the first chip 20 in a first direction and may be shorter than the first chip 20 in a second direction. The first direction and the second direction may be a vertical direction and a horizontal direction, respectively.

The second chip 40, which may be attached on the spacer 30, may be shorter than the spacer 30 in the vertical direction and may be longer than the spacer 30 in the horizontal direction.

The spacer 30 may be formed of silicon. Multiple spacer pads 31 may be formed on the spacer 30, and the spacer pads 31 may be large enough to be double wire-bonded.

The first and second chips 20 and 40 may be edge pad type chips. Chip pads 21 may be formed on two opposite corners of the first chip 20, and chip pads 41 and 42 may be formed along four sides of the second chip 40. The surfaces of the first and second chips 20 and 40 on which the chip pads 21, 41 and 42 may be formed may be active surfaces and the opposite sides of the active surfaces may be inactive surfaces, wherein the active surfaces of the first and second chips 20 and 40 may face the same direction. The inactive surfaces of the first and second chips 20 and 40 may be used for bonding the first and second chips 20 and 40 to other elements of the multi-chip package. The first chip 20, the second chip 40 and/or the spacer 30 may be bonded to each other using a dielectric adhesive.

The spacer 30 may include passive elements embedded therein, and some or all of the spacer pads 31 may be used as power and/or ground pads for applying power voltage and ground voltage to the passive element. The passive element may be a capacitor.

The spacer pads 31, which may be used as power and/or ground pads, may serve as electrodes of a capacitor, and the part of the spacer 30 which may not include the spacer pads 31, which may be formed of silicon, may serve as a dielectric layer of the capacitor. The spacer 30 may have a thickness of 80-200 μm.

Each of the spacer pads 31 may provide for electrical connection, such that the chip pads 42 of the second chip 40 may be electrically connected to the second substrate bonding pads 12 via the spacer pads 31.

Power and/or ground pads of the second chip 40 may be connected to second substrate bonding pads 12 via the power and/or ground pads of the spacer pads 31, which may improve the electrical characteristics, such as inductance, of the multi-chip package.

The chip pad 21 of the first chip 20 may be electrically connected to the first substrate bonding pad 11 and may use a first bonding wire 51. The height of a loop of the first bonding wire 51 may depend on the height of the spacer 30 between the first and second chips 20 and 40. The chip pad 41 on the second chip 40 and the third substrate bonding pad 13 may be electrically connected to each other using a second bonding wire 52.

The chip pad 42 on the second chip 40 and the second substrate bonding pad 12 may be electrically connected to each other via one of the spacer pads 31 which may use the third and/or fourth bonding wires 53 and/or 54.

In an exemplary embodiment of the present embodiment, the chip pad 42 and the second substrate bonding pad 12 may be electrically connected to each other via one of the spacer pads 31. The chip pad 42 and the second substrate bonding pad 12 may be connected (for example, directly connected) to each other using a single bonding wire.

The spacer pads 31, which may be used as power and/or ground pads, may be electrically connected to the power and/or ground pads of the first and/or second chips 20 and 40.

The first chip 20, the second chip 40, the spacer 30, the bonding wires 51, 52, 53, and 54 and connected portions there among may be included (for example, encapsulated) in a package body 60. A solder ball 70, which may serve as an external node, may be attached to each of the terminals 15 under the substrate 10. Solder balls 70 may be connected to the first through third substrate bonding pads 11 through 13 via circuit interconnections (not shown) which may be formed on the substrate 10 such that they may be electrically connected to the first chip 20, the spacer 30, and the second chip 40.

In the multi-chip package according to an exemplary embodiment of the present invention, the spacer 30 may serve as a passive element. The stability of wire bonding may be improved by wire-bonding the second chip 40 to the second substrate bonding pads 12 via the spacer 30.

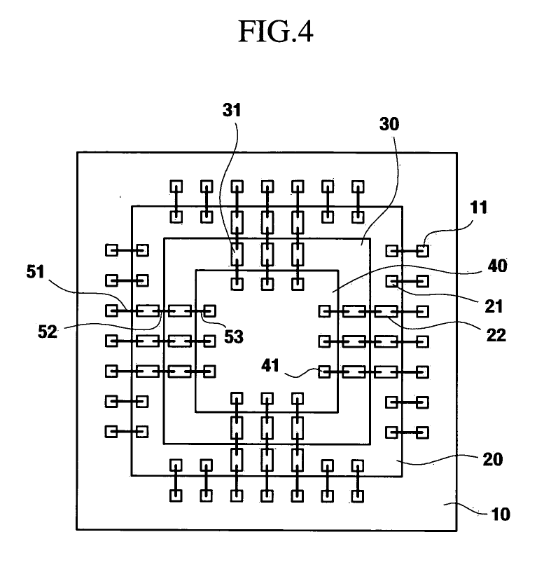

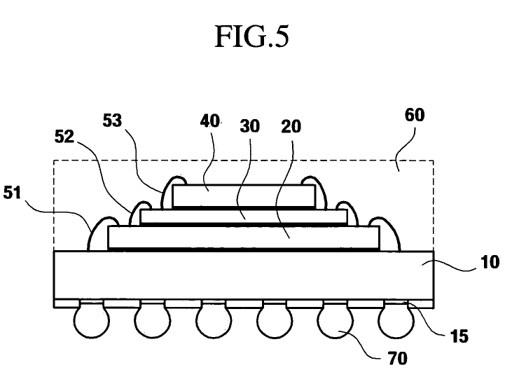

In another exemplary embodiment of the present invention, referring to FIGS. 4 and 5, a first chip 20 may be mounted on a substrate 10, on which multiple substrate bonding pads may be formed and under which multiple terminals 15 may be formed.

A spacer 30 which may have a smaller width and/or length than the first chip 20 may be attached to the first chip 20.

A second chip 40 which may have a smaller width and/or length than the spacer 30 may be attached to the spacer 30.

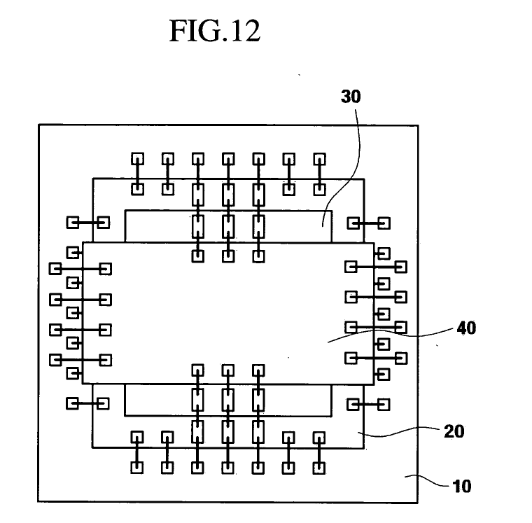

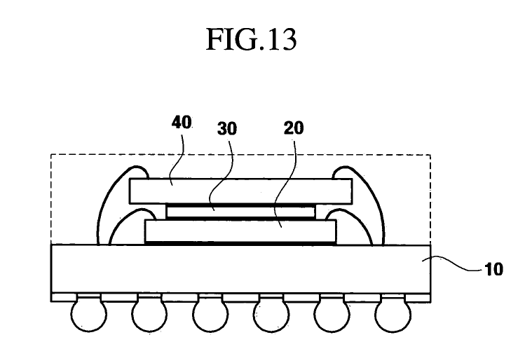

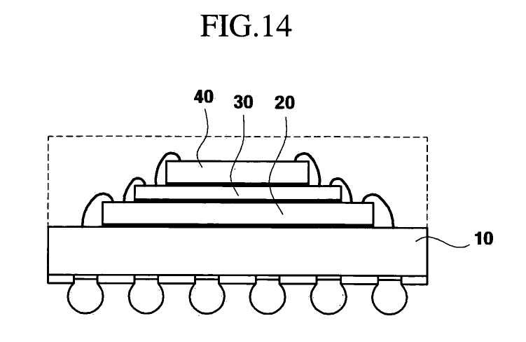

The second chip 40 may be formed to be longer than the spacer 30 in a vertical direction and/or a horizontal direction, as shown in FIGS. 12 through 14.

The spacer 30 may be formed of silicon and multiple spacer pads 31 may be formed on the spacer 30. The spacer pads 31 may be double wire-bonded.

The first and second chips 20 and 40 may be edge pad type chips. Chip pads 21 and 22 may be formed along all four sides of the first chip 20, and chip pads 41 may be formed along four sides of the second chip 40. The chip pads 22 of the first chip 20 may be larger than chip pads 21, such that they may be double wire-bonded.

The surfaces of the first and second chips 20 and 40, on which the chip pads 21 and 22 (or the chip pad 41) may be formed, may be active surfaces and the remainder of the surfaces of the first and second chips 20 and 40 may be inactive surfaces. The active surfaces of the first and second chips 20 and 40 may face the same direction. The inactive surfaces of the first and second chips 20 and 40 may be used for bonding the first and second chips 20 and 40 to other elements of the multi-chip package. The first chip 20 and the spacer 30 may be bonded to each other using a dielectric adhesive, and the spacer 30 and the second chip 40 may be bonded to each other using the dielectric adhesive.

The spacer 30 may include a passive element, and some or all of the spacer pads 31 may be used as power and/or ground pads for applying power voltage and/or ground voltage to the passive element. The passive element may be a capacitor.

The spacer pads 31, which may be used as power and/or ground pads, may serve as electrodes of a capacitor, and the part of the spacer 30 which may not include the spacer pads 31, may be formed of silicon and may serve as a dielectric layer of the capacitor. The spacer 30 may have a thickness of 80-200 μm.

Each of the spacer pads 31 may provide an electrical connection, such that the chip pad 41 of the second chip 40 may be electrically connected to the second substrate bonding pad 12. Power and/or ground pads of the second chip 40 may be connected to the second substrate bonding pads 12 via the power and/or ground pads of the spacer pads 31, and may improve the electrical characteristics, such as inductance, of the multi-chip package.

The chip pads 21 and 22 of the first chip may be electrically connected to the first substrate bonding pad 11 using a first bonding wire 51.

The spacer pads 31 may be electrically connected to the first substrate bonding pads 11 via the chip pads 22 of the first chip 20, using first and/or second bonding wires 51 and 52.

The chip pads 41 of the second chip 40 may be electrically connected to the first substrate bonding pad 11 via the spacer pads 31, and the chip pads 22 of the first chip 20 may use the first, second, and third bonding wires 51, 52, and 53, respectively. In an exemplary embodiment, the chip pads 41 of the second chip 40 may be electrically connected to the first substrate bonding pads 11 via the spacer pads 31 and/or the chip pads 22 of the first chip 20. The chip pads 41 of the second chip 40 may be electrically connected to the first substrate bonding pads 11 via the spacer pads 31 or the chip pads 22 of the first chip 20. The chip pads 41 of the second chip 40 may also be connected to the first substrate bonding pads 11.

The spacer pads 31, which may be used as power and/or ground pads, may be electrically connected to the power and/or ground pads of the first and/or second chips 20 and 40.

The first chip 20, the second chip 40, the spacer 30, the bonding wires 51, 52, 53, and 54 and connected portions there among may be included (for example, encapsulated) in a package body 60. Solder balls 70, which may serve as external nodes, may be attached to the terminals 15 under the substrate 10. The solder balls 70 may be connected to the first through third substrate bonding pads 11 through 13 via circuit interconnections (not shown) which may be formed on the substrate 10 such that they may be electrically connected to the first chip 20, the spacer 30, and the second chip 40.

The spacer 30 may serve as a passive element and the stability of the wire bonding may be improved.

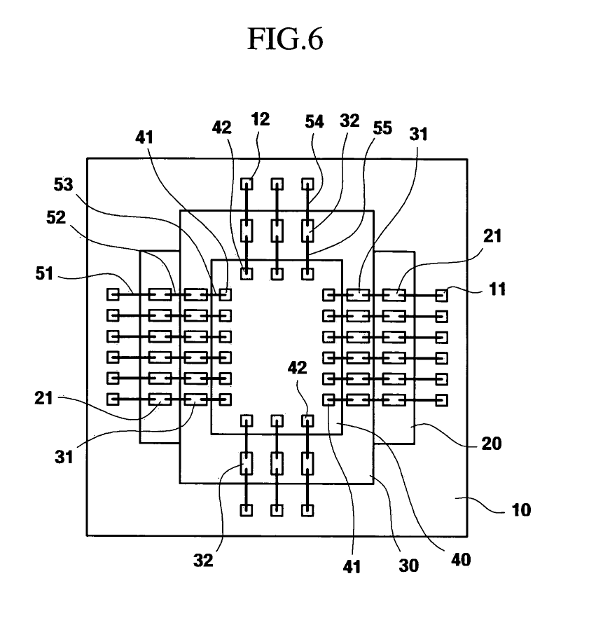

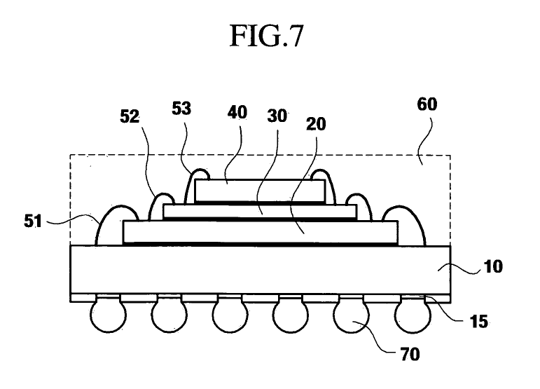

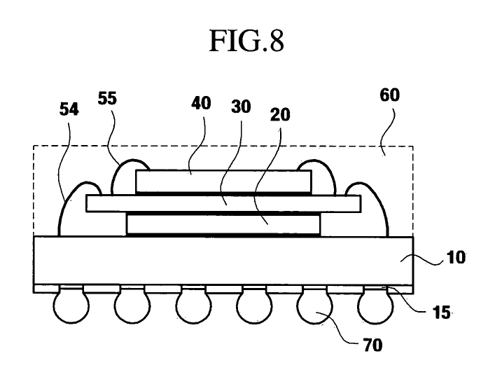

In another exemplary embodiment of the present invention, referring to FIGS. 6 through 8, a first chip 20 may be mounted on a substrate 10, on which multiple substrate bonding pads may be formed, and under which multiple terminals 15 may be formed.

The first substrate bonding pads 11 may be formed in a vertical direction, and/or the second substrate bonding pad 12 be formed in a horizontal direction.

A spacer 30 may be attached to the first chip 20. The spacer 30 may be longer than the first chip 20 in the vertical direction and may be shorter than the first chip 20 in the horizontal direction.

A second chip 40, which may have a smaller length and/or width than the spacer 30, may be formed on the spacer 30.

The spacer 30 may be formed of silicon. First and second spacer pads 31 and 32 may be formed on the spacer 30. The first spacer pad 31 may be formed in the vertical direction, and the second spacer pad 32 may be formed in the horizontal direction. The spacer pads 31 and 32 may be double wire-bonded.

The first and second chips 20 and 40 may be edge pad type chips. Chip pads 21 may be formed in two opposite corners of the first chip 20, and chip pads 41 and 42 may be formed along four sides of the second chip 40. The chip pads 21 may be double wire-bonded.

Supposing that the surfaces of the first and second chips 20 and 40 on which the chip pads 21, 41 and 42 may be formed, may be active surfaces and the remainder of the surfaces of the first and second chips 20 and 40 may be inactive surfaces, the active surfaces of the first and second chips 20 and 40 may face toward the same direction. The inactive surfaces of the first and second chips 20 and 40 may be used for bonding the first and second chips 20 and 40 to other elements of the multi-chip package. The first chip 20 and the spacer 30 may be bonded to each other using a dielectric adhesive. The spacer 30 and the second chip 40 may be bonded to each other using the dielectric adhesive.

The spacer 30 may include a passive element, and the spacer pads 31 and 32 may be used as power and/or ground pads for applying power voltage and/or ground voltage to the passive element. The passive element may be a capacitor.

The spacer pads 31 and 32, which may be used as power and/or ground pads, may serve as electrodes of a capacitor, and the part of the spacer 30 which may not include the spacer pads 31 and 32 may be formed of silicon, may serve as a dielectric layer of the capacitor. The spacer 30 may have a thickness of 80-200 μm.

Each of the spacer pads 31 and 32 may be electrically connected to the chip pads 41 and 42 of the second chip 40 which may be wire-bonded to the first and second substrate bonding pads 11 and 12, via the spacer pads 31 and 32, such that the chip pads 41 and 42 of the second chip 40 may be electrically connected to the first and second substrate bonding pads 11 and 12.

Power and/or ground pads of the second chip 40 may be connected to the first substrate bonding pad 11 via the power and/or ground pads of each of the spacer pads 31 and 32, and may improve the electrical characteristics, such as inductance, of the multi-chip package.

The chip pad 21 of the first chip 20 may be electrically connected to the first substrate bonding pad 11 using a first bonding wire 51.

The first spacer pads 31 may be electrically connected to the first substrate bonding pad 11 via the chip pads 21 of the first chip 20 and may use the first bonding wires 51 and second bonding wires 52.

The chip pads 41 on the second chip 40 may be electrically connected to the first substrate bonding pads 11 via the first spacer pad 31 and the chip pads 21 of the first chip 20 using the first, second, and third bonding wires 51, 52, and 53, respectively.

The second spacer pads 32 may be electrically connected to the second substrate bonding pads 12 using fourth bonding wires 54.

The chip pads 42 on the second chip 20 may be electrically connected to the second substrate bonding pads 12 via the second spacer pads 32, and may use the fourth bonding wires 54 and fifth bonding wires 55.

The spacer pads 31, which may be used as power and/or ground pads, may be electrically connected to the power and/or ground pads of the first and second chips 20 and 40.

The first chip 20, the second chip 40, the spacer 30, the bonding wires 51, 52, 53, 54, and 55 and connected portions thereamong may be included (for example, encapsulated) in a package body 60. Solder balls 70, which may serve as external nodes, may be attached to the terminals 15 under the substrate 10. The solder balls 70 may be connected to the first through third substrate bonding pads 11 through 13 via circuit interconnections (not shown) which may be formed on the substrate 10 such that they may be electrically connected to the first chip 20, the spacer 30, and the second chip 40.

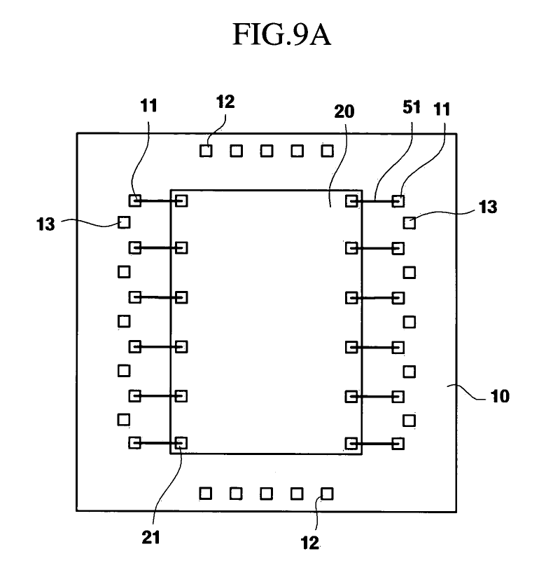

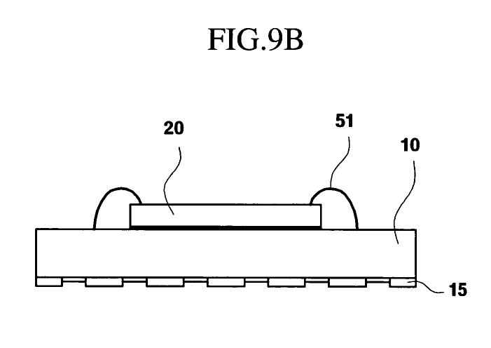

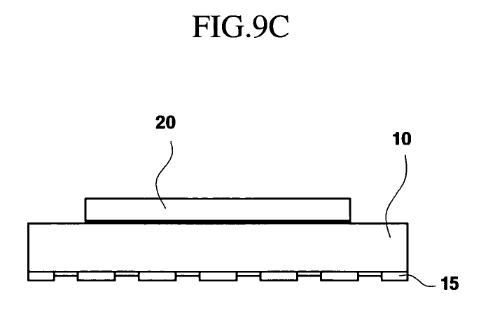

In another exemplary embodiment of the present invention, referring to FIGS. 9A through 9C, the inactive surface of the first chip 20 may be fixed onto the substrate 10. The first through third substrate bonding pads 11 through 13 may be formed on the substrate 10 and multiple terminals 15 may be formed under the substrate 10, using an adhesive, such as epoxy, a dielectric tape, or the like.

A primary wire bonding may be performed using the first bonding wire 51, such as a gold (Au) wire or the like, such that the chip pad 21 may be electrically connected to the first substrate bonding pad 11 on the substrate 10.

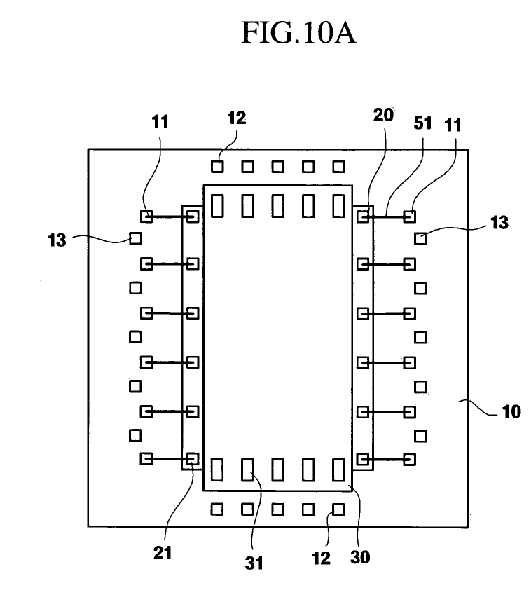

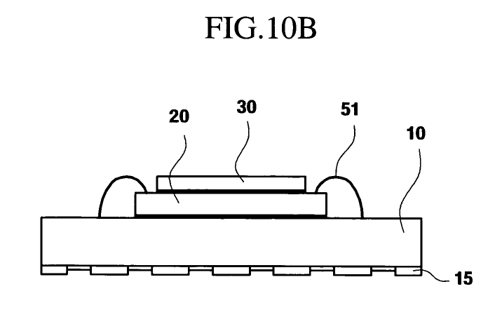

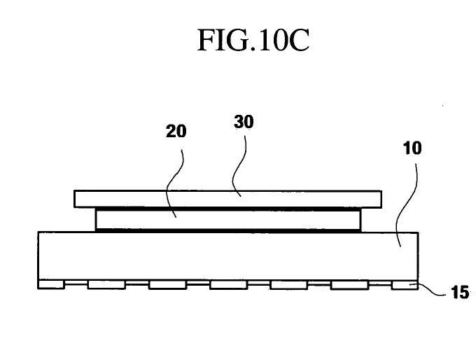

Referring to FIGS. 10A through 10C, the spacer 30 may be bonded to the first chip 20 using the adhesive such that the spacer 30 may be longer than the first chip 20 in the vertical direction and/or shorter than the first chip 20 in the horizontal direction.

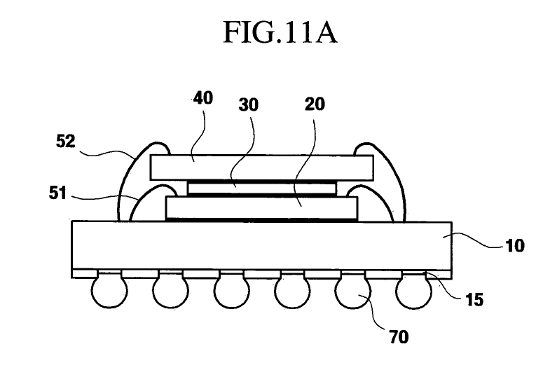

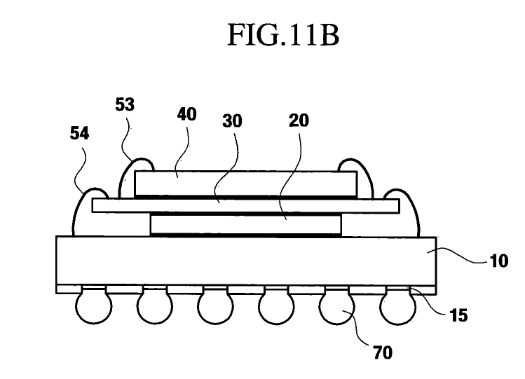

Referring to FIGS. 1, 11A and 11B, the second chip 40 may be bonded to the spacer 30 using the adhesive such that the second chip 40 may be longer than the spacer 30 in the horizontal direction and/or shorter than the spacer 30 in the vertical direction.

Secondary wire bonding may be performed using the second through fourth bonding wires 52 through 54.

The chip pad 41 on the second chip 40 may be wire-bonded to the third substrate bonding pad 13 using the second bonding wire 52 such that they may be electrically connected to each other.

The chip pad 42 on the second chip 40 may be wire-bonded to a spacer pad 31 using the third bonding wire 53 such that they may be electrically connected to each other.

The second substrate bonding pad 12 may be wire-bonded to a spacer pad 31 using the fourth bonding wire 54 such that they may be electrically connected to each other.

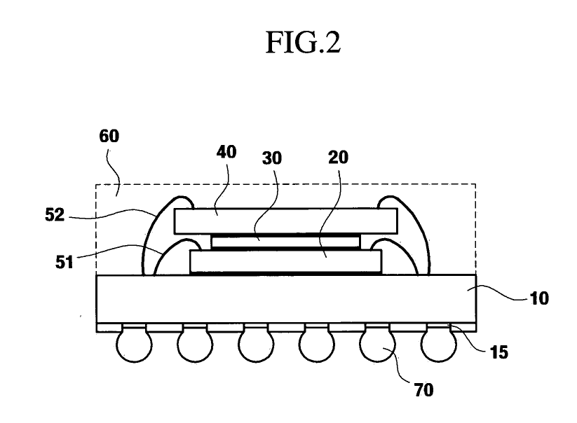

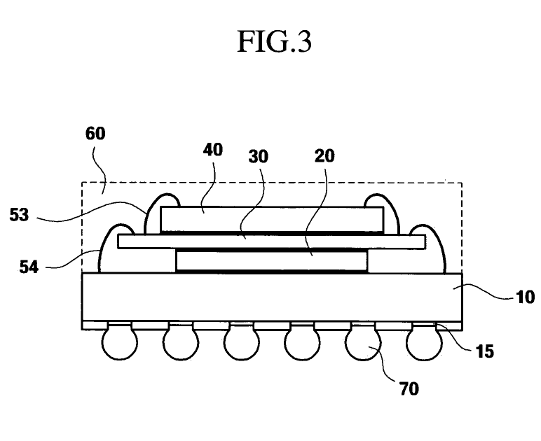

As shown in FIGS. 2 and 3, the package body 60 may be made of epoxy resin, or the like, such that the first chip 20, the second chip 40, the spacer 30, the bonding wires 51 through 54, and connected portions thereamong may be included (for example, encapsulated) therein. Solder balls 70, which may serve as external nodes, may be attached to the terminals 15.

Multiple multi-chip packages may be manufactured in a batch type and separated from one another.

Although exemplary embodiments of the present invention disclose substrate bonding pads which may be formed on and multiple terminals which may be formed under the substrate, it will be understood that the pads and terminals may be used interchangeably as desired by one of ordinary skill in the art.

Although the spacer pads may be double-wire bonded as disclosed in the exemplary embodiments of the present invention, it will be understood that the spacer pads may have any number of wires bonded to them as desired by one of ordinary skill in the art.

While the present invention may have been shown and described through exemplary embodiments thereof with reference to the accompanying drawings, it may be understood by those of ordinary skill in the art that various changes in form and details may be made therein without departing from the spirit and scope of the present invention as defined by the following claims.

According to the present invention, in a multi-chip package in which multiple chips may be vertically stacked with spacers interposed between each of the chips, the spacers may serve as passive elements and the stability of the wire bonding and/or the electrical characteristics of the multi-chip package may be improved.

1. A multi-chip package, comprising:
a substrate, on which multiple substrate bonding pads, including at least power and ground pads, are formed and under which multiple terminals are formed;
a first semiconductor chip formed on the substrate having multiple pads, including at least power and ground pads;
a spacer, formed on the first semiconductor chip, having at least one passive element with at least power and ground pads formed thereon;
a second semiconductor chip formed on the spacer having multiple pads, including at least power and ground pads; and
wherein the first and second semiconductor chips and the power and ground pads of the spacer are electrically connected to the power and ground pads of the substrate bonding pads.

2. A multi-chip package, comprising:
a substrate, on which multiple substrate bonding pads, including at least power and ground pads, are formed and under which multiple terminals are formed;
a first semiconductor chip formed on the substrate having multiple pads, including at least power and ground pads;
a spacer, formed on the first semiconductor chip, having at least one passive element with at least power and ground pads formed thereon, the at least one passive element extending longer than the first semiconductor chip in at least one of first and second directions with respect to the first semiconductor chip, the first and second directions being orthogonal to each other;
a second semiconductor chip, formed on the spacer, having multiple pads, including at least power and ground pads; and
wherein the first and second semiconductor chips and the power and ground pads of the spacer are electrically connected to the power and ground pads of the substrate bonding pads.

3. The multi-chip package of claim 2, wherein the second semiconductor chip has a length in a first direction and another length in a second direction orthogonal to the first direction, and is shorter than the spacer in at least one of the first and second directions.

4. The multi-chip package of claim 3, wherein the power and ground pads of the second semiconductor chip are electrically connected to the power and ground pads of the substrate via and the power and ground pads of the spacer.

5. The multi-chip package of claim 4, wherein the power and ground pads of the second semiconductor chip are electrically connected to the power and ground pads of the substrate via the power and ground pads of the spacer and the power and ground pads of the first semiconductor chip.

6. The multi-chip package of claim 5, wherein the spacer is formed of silicon to have a thickness of 80-120 μm, the at least one passive element included in the spacer is a capacitor, and the power and ground pads of the spacer serve as electrodes of the capacitor.

7. The multi-chip package of claim 6, wherein the electrical connection is formed by wire bonding.

8. The multi-chip package of claim 7, wherein the first semiconductor chip, the second semiconductor chip, the spacer, and connected portions thereamong are encapsulated.

9. The multi-chip package of claim 4, wherein the power and ground pads of the first semiconductor chip are electrically connected to the power and ground pads of the substrate.

10. The multi-chip package of claim 9, wherein the spacer is formed of silicon to have a thickness of 80-120 μm, the at least one passive element included in the spacer is a capacitor, and the power and ground pads of the spacer serve as electrodes of the capacitor.

11. The multi-chip package of claim 10, wherein the electrical connection is formed by wire bonding.

12. The multi-chip package of claim 11, wherein the first semiconductor chip, the second semiconductor chip, the spacer, and connected portions thereamong are encapsulated.

13. The multi-chip package of claim 3, wherein the second semiconductor chip is shorter than the spacer in at least one of the first and second directions of the spacer.

14. The multi-chip package of claim 13, wherein the power and ground pads of the second semiconductor chip are electrically connected to the power and ground pads of the substrate via and the power and ground pads of the spacer.

15. The multi-chip package of claim 14, wherein the power and ground pads of the second semiconductor chip are electrically connected to the power and ground pads of the substrate via the power and ground pads of the spacer and the power and ground pads of the first semiconductor chip.

16. The multi-chip package of claim 15, wherein the spacer is formed of silicon to have a thickness of 80-120 μm, the at least one passive element included in the spacer is a capacitor, and the power and ground pads of the spacer serve as electrodes of the capacitor.

17. The multi-chip package of claim 16, wherein the electrical connection is formed by wire bonding.

18. The multi-chip package of claim 17, wherein the first semiconductor chip, the second semiconductor chip, the spacer, and connected portions thereamong are encapsulated.

19. The multi-chip package of claim 14, wherein the power and ground pads of the first semiconductor chip are electrically connected to the power and ground pads of the substrate.

20. The multi-chip package of claim 19, wherein the spacer is formed of silicon to have a thickness of 80-120 μm, the at least one passive element included in the spacer is a capacitor, and the power and ground pads of the spacer serve as electrodes of the capacitor.

21. The multi-chip package of claim 20, wherein the electrical connection is formed through wire bonding.

22. The multi-chip package of claim 21, wherein the first semiconductor chip, the second semiconductor chip, the spacer, and connected portions thereamong are encapsulated.

23. A multi-chip package, comprising:
a substrate, on which multiple substrate bonding pads, including at least power and ground pads, are formed and under which multiple terminals are formed;
a first semiconductor chip formed on the substrate having multiple pads, including at least power and ground pads;
a spacer, formed on the first semiconductor chip, having at least one passive element with power and ground pads formed thereon, the at least one passive element being shorter than the first semiconductor chip in any one of first and second directions with respect to the first semiconductor chip, the first and second directions being orthogonal to each other;
a second semiconductor chip, formed on the spacer, having multiple pads, including at least power and ground pads; and
wherein the first and second semiconductor chips and the power and ground pads of the spacer are electrically connected to the power and ground pads of the substrate bonding pads.

24. A multi-chip package, comprising:
a substrate, on which multiple substrate bonding pads, including at least power and ground pads, are formed and under which multiple terminals are formed;
a first semiconductor chip having multiple pads, including at least power and ground pads;
a spacer, having at least one passive element with at least power and ground pads formed thereon; and
a second semiconductor chip having multiple pads, including at least power and ground pads; wherein
the first semiconductor chip, the second semiconductor chip, and the spacer are placed on the substrate,
the first semiconductor chip, second semiconductor chip, and the power and ground pads of the spacer are electrically connected to the power and ground pads of the substrate bonding pads,
at least two selected from a group including the first semiconductor chip, the second semiconductor chip, and the spacer, are each greater than, less than, or equal in length in at least one of a first and a second direction with respect to the at least one not selected from the group.

25. A method of manufacturing a multi-chip package comprising:
forming multiple substrate bonding pads, including at least power and ground pads, on and multiple terminals under a substrate;
forming multiple pads, including at least power and ground pads, on a first semiconductor chip;
forming at least one passive element, including at least power and ground pads on a spacer;
forming multiple pads, including at least power and ground pads formed thereon, on a second semiconductor chip;
placing the first semiconductor chip, the second semiconductor chip, and the spacer, on the substrate; and
electrically connecting the first semiconductor chip, the second semiconductor chip and the power and ground pads of the spacer to the power and ground pads of the substrate bonding pads; wherein
at least two selected from a group including the first semiconductor chip, the second semiconductor chip, and the spacer, are each greater than, less than, or equal in length in at least one of a first and a second direction with respect to the at least one not selected from the group.
